(19) United States
(12) Patent Application Publication
(10) Pub. No.: US 2026/0358852 A1
(43) Pub. Date: Nov. 12, 2026

(54) BANDGAP REFERENCE CIRCUIT

(71) Applicant: EMEMORY TECHNOLOGY INC., HSINCHU (TW)

(72) Inventor: KAI-JIE FAN, HSINCHU COUNTY (TW)

(21) Appl. No.: 19/666,397

(22) Filed: May 4, 2026

Related U.S. Application Data
(60) Provisional application No. 63/804,007, filed on May 12, 2025.

(51) Int. Cl. G05F 3/26

(52) U.S. Cl. CPC G05F 3/262

(57) ABSTRACT

A bandgap reference circuit generates a reference voltage through an output node. The bandgap reference circuit includes a first current source generating a first current through a first node, a second current source generating a second current through a second node, a third current source generating a third current through the output node, an amplifier, a load element for receiving the third current, a first BJT for receiving the first current, a second BJT for receiving the second current, a resistor coupled between the first node and the first BJT, a first capacitor coupled between the first node and a system voltage, and a second capacitor coupled between the second node and a system voltage. The amplifier has input terminals coupled to the first node and the second node respectively, and an output terminal for controlling the first, the second, and the third current sources.

### CROSS REFERENCE

This application claims the benefit of prior-filed U.S. provisional application No. 63/804,007, filed on May 12, 2025, which is incorporated by reference in its entirety.

### TECHNICAL FIELD

The present disclosure relates to a bandgap reference circuit, and more particularly, to a bandgap reference circuit capable for providing a stable reference voltage.

### DISCUSSION OF THE BACKGROUND

A bandgap reference circuit is a type of voltage reference circuit that provides a stable and accurate reference voltage for use in various electronic systems. It is designed to produce a constant output voltage that is relatively immune to changes in temperature, power supply voltage, and other environmental factors.

However, such task can be challenging as the operating condition may vary during the operation. For example, when there is a ripple in the ground voltage or the power voltage, the asymmetric structure of the bandgap reference circuit may cause jitter to the reference voltage outputted by the bandgap reference circuit, thereby causing instability to the system.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a bandgap reference circuit for generating and outputting a reference voltage through an output node. The bandgap reference circuit includes a first current source, a second current source, a third current source, an amplifier, a load element, a first bipolar junction transistor (BJT), a second BJT, a resistor, a first capacitor, and a second capacitor. The first current source generates a first current through a first node, the second current source generates a second current through a second node, and the third current source generates a third current through the output node. The amplifier has a first input terminal coupled to the first node, a second input terminal coupled to the second node, and an output terminal for controlling the first current source, the second current source, and the third current source. The load element is coupled to the output node for receiving the third current. The first BJT receives the first current, and the second BJT receives the second current. The resistor is coupled between the first node and the first BJT. The first capacitor has a first terminal coupled to the first node, and a second terminal for receive a system voltage. The second capacitor has a first terminal coupled to the second node, and a second terminal for receiving the system voltage.

Another aspect of the present disclosure provides a bandgap reference circuit for generating and outputting a reference voltage. The bandgap reference circuit includes an amplifier, a first transistor path, a second transistor path, a balancing circuit, and a charging circuit. The amplifier has a first input terminal coupled to a first node and a second input terminal coupled to a second node. The first transistor path is coupled to the first node and the second transistor path is coupled to the second node. The first and second transistor paths respectively generate a first current and a second current for generating the reference voltage. The balancing circuit is coupled to the first node and the second node, wherein the balancing circuit equalize a first impedance at the first node and a second impedance at the second node so as to reduce a voltage difference between the first node and the second node when a ripple appears in a system voltage. The charging circuit is coupled to the first node and the second node. For a predetermined period upon enablement of the bandgap reference circuit, the charging circuit generates a first charging current through the first node and a second charging current through the second node to accelerate raising a voltage at the first node and a voltage at the second node into an operating voltage range of the amplifier.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a bandgap reference circuit according to a comparative embodiment of the present disclosure.

FIG. 2 shows a bandgap reference circuit according to one embodiment of the present disclosure.

FIG. 3 shows a bandgap reference circuit according to another embodiment of the present disclosure.

FIG. 4 shows the current sources in FIG. 3 with a bias circuit according to one embodiment of the present disclosure.

FIG. 5 shows a bandgap reference circuit according to another embodiment of the present disclosure.

### DETAILED DESCRIPTION

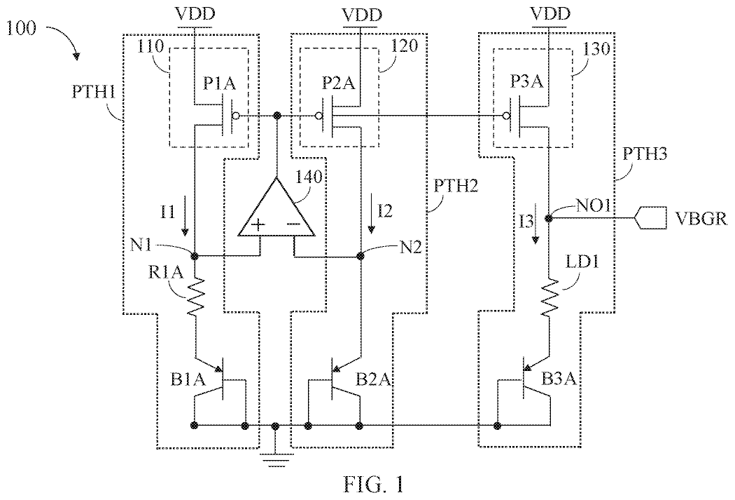

FIG. 1 shows a bandgap reference circuit 100 according to a comparative embodiment of the present disclosure. In the present embodiment, the bandgap reference circuit 100 can generate and output a reference voltage VBGR through an output node NO1. The bandgap reference circuit 100 includes transistor paths PTH1, PTH2, and an amplifier 140. The amplifier 140 has a first input terminal coupled to a node N1 and a second input terminal coupled to a node N2. The transistor path PTH1 is coupled to the node N1, and the transistor path PTH2 is coupled to the node N2. The transistor paths PTH1 and PTH2 respectively generate a current I1 and a current I2 for generating the reference voltage VBGR.

Specifically, the transistor path PTH1 may include a current source 110, a resistor RIA, and a bipolar junction transistor (BJT) B1A. The transistor path PTH2 may include a current source 120, and a BJT B2A. In addition, the bandgap reference circuit 100 may further include a transistor path PTH3. The transistor path PTH3 is coupled to the output node NO1, and generate a current I3 for generating the reference voltage VBGR. The transistor path PTH3 includes a current source 130, a load element LD1, and a BJT B3A.

The current source 110 can generate a current I1 through a node N1, the current source 120 can generate a current I2 through a node N2, and the current source 130 can generate a current I3 through a node NO1. The amplifier 140 has a first input terminal coupled to the node N1, a second input terminal coupled to the node N2, and an output terminal for controlling the current sources 110, 120, and 130. The load element LD1 is coupled to the output node NO1 and receives the current I3. The resistor R1A is coupled between the node N1 and the BJT BIA. The BJT BIA receives the current I1, and the BJT B2A receives the current I2.

In some embodiments, the current source 110 may include a P-channel metal-oxide-semiconductor (PMOS) transistor P1A having a first terminal coupled to a power voltage VDD, a second terminal coupled to the node N1 and a control terminal coupled to the output terminal of the amplifier 140. The current source 120 may include a PMOS transistor P2A having a first terminal coupled to the power voltage VDD, a second terminal coupled to the node N2, and a control terminal coupled to the output terminal of the amplifier 140. The current source 130 may include a PMOS transistor P3A having a first terminal coupled to the power voltage VDD, a second terminal coupled to the output node NO1, and a control terminal coupled to the output terminal of the amplifier 140.

Furthermore, the resistor R1A has a first terminal coupled to the node N1, and a second terminal. The BJT BIA has a first terminal coupled to the second terminal of the resistor RIA, a second terminal for receiving the system voltage, and a control terminal coupled to the second terminal of the BJT BIA. In some embodiments, the system voltage can be the reference ground of the bandgap reference circuit 100. The BJT B2A has a first terminal coupled to the second node N2, a second terminal configured to receive the system voltage, and a control terminal coupled to the second terminal of the BJT B2A. The load element LD1 has a first terminal coupled to the output node NO1, and a second terminal. The BJT B3A has a first terminal coupled to a second terminal of the load element LD1, a second terminal for receiving the system voltage, and a control terminal coupled to the second terminal of the BJT B3A. In the present embodiment, the BJTs B1A, B2A, and B3A are NPN BJTs.

In the present embodiment, the first input terminal of the amplifier 140 is a non-inverting input terminal, and the second input terminal of the amplifier is an inverting input terminal. In such case, the amplifier 140 can keep the voltage VA at the node N1 at the same level as the voltage VB at the node N2 in a stable state, and thus, the PMOS transistors P1A, P2A, and P3A can be deemed as a current mirror. Therefore, the current I3 conducted by the transistor P3A should be equal to the current I1 conducted by the transistor P1A and the current I2 conducted by the transistor P2A (when the PMOS transistors P1A, P2A, and P3A have the same width to length ratio). In addition, the current I1 is related to the resistance of the resistor R1A and the base-emitter voltage VBE of the BJT BIA, which exhibit opposite responses to temperature variation. That is, the resistance of the resistor R1A has a positive temperature coefficient while the base-emitter voltage VBE of the BJT BIA has a negative temperature coefficient. Therefore, by properly selecting the resistor RIA, the current I1 can be substantially immune to the changes in temperature, and so as the reference voltage VBGR provided by the bandgap reference circuit 100.

However, when there is a ripple in the system voltage (i.e., the reference ground), the variation caused to the voltage VA at the node N1 can be different from the variation caused to the voltage VB at the node N2 since the impedance at the node N1 is different from the impedance at the node N2. For example, the variation vₐ of the voltage VA at the node N1 and the variation v_{b} of the voltage VB at the node N2 can be represented by formulas (1) and (2).

$${v}_{a} = {v}_{gnd} \frac{{r}_{mc}}{{r}_{e 1} + R 1 A + {r}_{mc}} \qquad formula ( 1 )$$

$${v}_{b} = {v}_{gnd} \frac{{r}_{mc}}{{r}_{e 2} + {r}_{mc}} \qquad formula ( 2 )$$

In formulas (1) and (2), v_{gnd} represents the variation of the reference ground (i.e., the small signal of the reference ground), r_{mc} represents the equivalent impedance of the current mirror formed by the current sources 110, 120, and 130, rₑ₁ represents the equivalent impedance of the BJT BIA, and rₑ₂ represents the equivalent impedance of the BJT B2A. In other words, the variation vₐ the voltage VA at the node N1 and the variation v_{b} of the voltage VB at the node N2 are determined by the impedance division at the nodes N1 and N2.

It should be noticed that, in the present embodiment, an emitter area of the BJT BIA can be greater than an emitter area of the BJT B2A. Alternatively, the BJT BIA may be implemented by a plurality of BJTs coupled in parallel with their dimensions same as that of the BJT B2A. Therefore, the equivalent impedance rₑ₁ is smaller than the equivalent impedance rₑ₂, and the sum of the impedance rₑ₁ and the impedance of the resistor R1A can also be smaller than the impedance rₑ₂. As a result, the voltage VA will be greater than the voltage VB when the ripple of the system voltage appears, and the difference can be amplified by the amplifier 140, thereby causing instability to the reference voltage VBGR generated by the bandgap reference circuit 100.

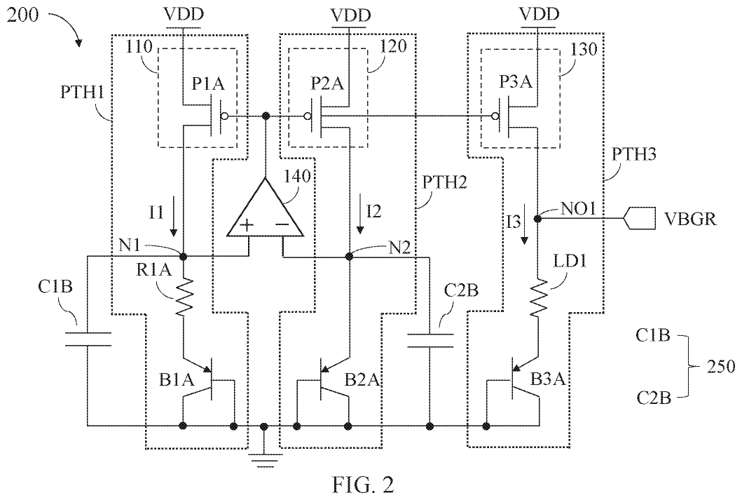

To reduce the instability of the reference voltage VBGR caused by the ripple of the system voltage, capacitors can be added to the nodes N1 and N2 so as to dominate the impedance at the nodes N1 and N2 when the ripple appears. FIG. 2 shows a bandgap reference circuit 200 according to one embodiment of the present disclosure.

The bandgap reference circuit 200 is different from the bandgap reference circuit 100 in that the bandgap reference circuit 200 further includes a balancing circuit 250. The balancing circuit 250 is coupled to the node N1 and the node N2. The balancing circuit 250 can equalize an impedance at the node N1 and an impedance at the node N2 so as to reduce a voltage difference between the node N1 and the node N2 when the ripple appears in a system voltage.

Specifically, the balancing circuit 250 may include capacitors C1B and C2B. The capacitor C1B has a first terminal coupled to the node N1, and a second terminal for receiving the system voltage. The capacitor C2B has a first terminal coupled to the node N2, and a second terminal for receiving the system voltage. In addition, the capacitance of the capacitor C1B can be same as the capacitance of the capacitor C2B.

Furthermore, in the present embodiment, an impedance caused by the capacitor C1B at the node N1 and the impedance caused by the capacitor C2B at the node N2 for the ripple of the system voltage can be lower than the impedance (i.e., the resistance in this case) of the BJT BIA and the impedance of the BJT B2A for the ripple of the system voltage. In such case, the impedance of the capacitor C1B can dominate the impedance at the node N1 and the impedance of the capacitor C2B can dominate the impedance at the node N2, so the variation vₐ and v_{b} caused by the ripple will become close, and the difference between the voltage VA and VB can be reduced, thereby allowing the bandgap reference circuit 200 to provide the reference voltage VBGR in a more stable manner even when the ripple appears.

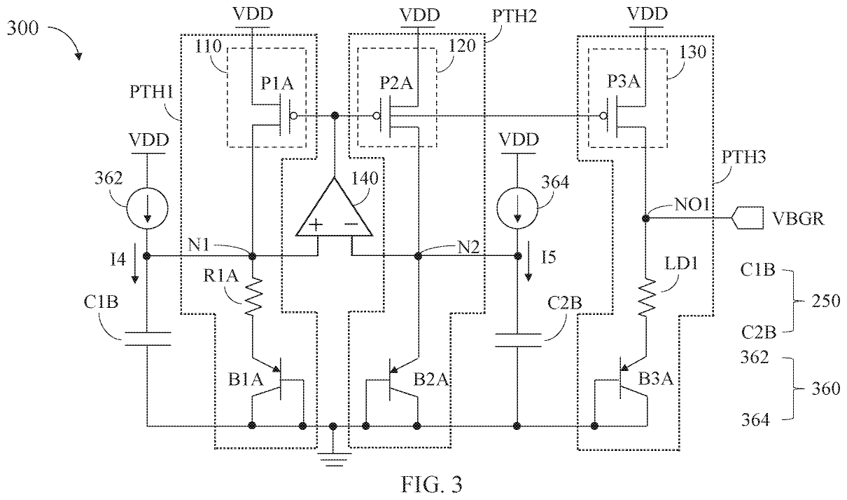

FIG. 3 shows a bandgap reference circuit 300 according to another embodiment of the present disclosure. The bandgap reference circuit 300 is different from the bandgap reference circuit 200 in that the bandgap reference circuit 300 further includes a charging circuit 360. The charging circuit 360 is coupled to the node N1 and the node N2. In the present embodiment, for a predetermined period upon enablement of the bandgap reference circuit 300, the charging circuit 360 can generate a charging current I4 through the node N1 and a charging current I5 through the node N2 to accelerate raising a voltage at the node N1 and a voltage at the node N2 into an operating voltage range of the amplifier 140. For example, the charging circuit 360 includes current sources 362 and 364. The current source 362 can generate a current I4 through the node N1 for a predetermined charging period when the bandgap reference circuit 300 is enabled, so as to charge the capacitor C1B and raise the voltage VA at the node N1 to enter the operating voltage range of the amplifier 140, thereby allowing the bandgap reference circuit 300 to enter the stable state sooner.

Specifically, in some embodiments, the voltage VA at the node N1 can be calculated by multiplying the current I4 with a length of the predetermined charging period and dividing the product of the current I4 and the length of the predetermined charging period by the capacitance of the capacitor C1B. In other words, the length of the predetermined charging period and the current I4 can be determined according to the criterion to ensure that the voltage VA can be within the operating voltage range of the amplifier 140 after charging. Similarly, the current source 364 can generate a current I5 through the node N2 for the predetermined charging period when the bandgap reference circuit 300 is enabled, so as to charge the capacitor C2B and raise the voltage VB at the node N2 to enter the operating voltage range of the amplifier 140.

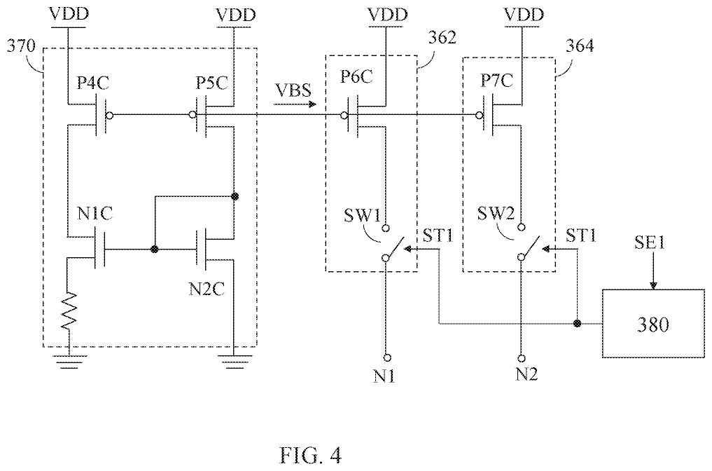

In some embodiments, the bandgap reference circuit 300 can further include a bias circuit for providing the bias voltage to the current sources 362 and 364 of the charging circuit 360. FIG. 4 shows the current sources 362 and 364 with a bias circuit 370 according to one embodiment of the present disclosure.

As shown in FIG. 4, the bias circuit 370 includes PMOS transistors P4C, P5C and NMOS transistors N1C and N2C. The PMOS transistor P4C has a first terminal for receiving the power voltage VDD, a second terminal, and a control terminal for providing the bias voltage VBS. The PMOS P5C has a first terminal for receiving the power voltage VDD, a second terminal, and a control terminal coupled to the control terminal of the PMOS transistor P4C. The NMOS transistor N1C has a first terminal coupled to the second terminal of the PMOS P4C transistor, a second terminal for receiving the system voltage, and a control terminal. The NMOS transistor N2C has a first terminal coupled to the second terminal of the PMOS transistor P5C, a second terminal for receiving the system voltage, and the control terminal coupled to the first terminal of the NMOS transistor N2C.

In addition, the current source 362 includes a PMOS transistor P6C and a switch SW1. The PMOS transistor P6C has a first terminal for receiving the power voltage VDD, a second terminal, and a control terminal for receiving the bias voltage VBS. The switch SW1 has a first terminal coupled to the second terminal of the PMOS transistor P6C, a second terminal coupled to the node N1, and a control terminal for receiving a start signal ST1. The current source 364 includes a PMOS transistor P7C and a switch SW2. The PMOS transistor P7C has a first terminal for receiving the power voltage VDD, a second terminal, and a control terminal for receiving the bias voltage VBS. The switch SW2 has a first terminal coupled to the second terminal of the PMOS transistor P7C, a second terminal coupled to the node N2, and a control terminal for receiving the start signal ST1.

In some embodiments, the bandgap reference circuit 300 may further include a pulse generator 380 for generating the start signal ST1 according to the enable signal SE1 of the bandgap reference circuit 300. For example, the pulse generator 380 can generate the start signal ST1 with a pulse width equal to the predetermined charging period when the enable signal SE1 of the bandgap reference circuit 300 is transitioning to a high logic level (assuming that the bandgap reference circuit 300 is enabled when the enable signal SE1 becomes the high logic level). Consequently, the nodes N1 and N2 can be charged by the current I4 and I5 for the predetermined charging period.

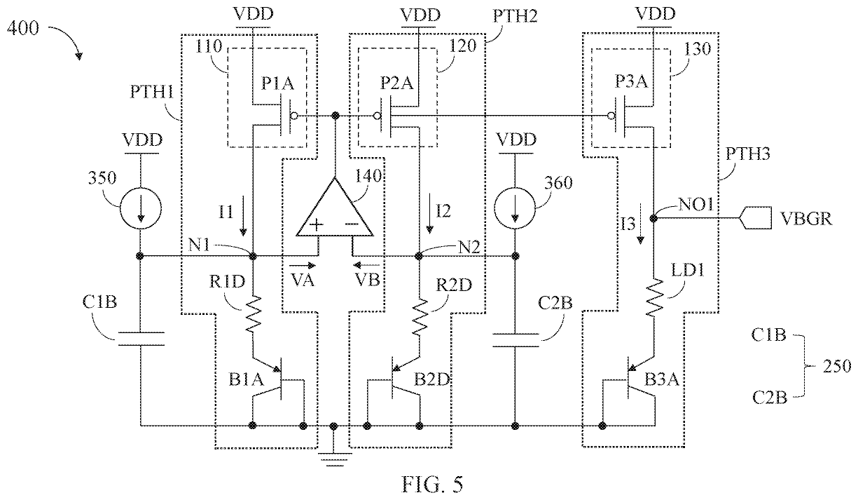

FIG. 5 shows a bandgap reference circuit 400 according to another embodiment of the present disclosure. The bandgap reference circuit 400 is different from the bandgap reference circuit 300 in that a resistor R2D is added between the BJT B2D and the node N2. Specifically, the resistor R2D has a first terminal coupled to the node N2, and a second terminal. The BJT B2D has a first terminal coupled to the second terminal of the resistor R2D, a second terminal for receiving the system voltage, and a control terminal coupled to the second terminal of the BJT B2D.

Furthermore, the resistance of the resistor RID in the bandgap reference circuit 400 can be greater than the resistance of the resistor RIA in the bandgap reference circuit 300 by the resistance of the resistor R2D.

That is, in some embodiments, the resistor RID can be implemented by the resistor R1A coupled in series with another resistor having a resistance same as that of the resistor R2D. In addition, the resistance of the resistor RID and the resistance of the resistor R2D can both be greater than the on-resistance of the BJT BIA (i.e., rₑ₁ in formula (1)) and the on-resistance of the second BJT B2D (i.e., rₑ₂ in formula (2)), so that the capacitor C1B and the resistor RID can dominate the impedance at the node N1 for the ripple of the system voltage and the capacitor C2B and the resistor R2D can dominate the impedance at the node N2 for the ripple of the system voltage. As a result, the difference between the impedance at the node N1 and the impedance at the node N2 can be further reduced, thereby reducing the difference between the voltages VA and VB when the ripple of the system voltage appears.

Furthermore, in some embodiments, with the resistors RID and R2D, the time period required by the current source 362 and 364 to charge the nodes N1 and N2 when the bandgap reference circuit 400 is enabled can be reduced. In some embodiments, as the resistors RID and R2D can dominate the impedance at the node N1 and the impedance at the node N2 respectively for the ripple of the system voltage, the capacitor C1B and C2B may be omitted along with the current sources 362 and 364.

In summary, the bandgap reference circuits provided by the embodiments of the present disclosure can adopt capacitors and/or resistors for balancing the impedances at the input terminals of the amplifier for the ripples of the system voltage, so that the difference between the voltages at the input terminals of the amplifier can be reduced when the ripple of the system voltage appears, thereby stabilizing the reference voltages outputted by the bandgap reference circuits.

What is claimed is:

1. A bandgap reference circuit configured to generate and output a reference voltage through an output node and comprising:
a first current source configured to generate a first current through a first node;
a second current source configured to generate a second current through a second node;
a third current source configured to generate a third current through the output node;
an amplifier having a first input terminal coupled to the first node, a second input terminal coupled to the second node, and an output terminal configured to control the first current source, the second current source, and the third current source;
a load element coupled to the output node and configured to receive the third current;
a first bipolar junction transistor (BJT) configured to receive the first current;
a second BJT configured to receive the second current;
a first resistor coupled between the first node and the first BJT;
a first capacitor having a first terminal coupled to the first node, and a second terminal configured to receive a system voltage; and
a second capacitor having a first terminal coupled to the second node, and a second terminal configured to receive the system voltage.

2. The bandgap reference circuit of claim 1, wherein the first current source comprises a first P-channel metal-oxide-semiconductor (PMOS) transistor having a first terminal coupled to a power voltage, a second terminal coupled to the first node and a control terminal coupled to the output terminal of the amplifier.

3. The bandgap reference circuit of claim 1, wherein the second current source comprises a second P-channel metal-oxide-semiconductor (PMOS) transistor having a first terminal coupled to a power voltage, a second terminal coupled to the second node and a control terminal coupled to the output terminal of the amplifier.

4. The bandgap reference circuit of claim 1, wherein the third current source comprises a third P-channel metal-oxide-semiconductor (PMOS) transistor having a first terminal coupled to a power voltage, a second terminal coupled to the output node and a control terminal coupled to the output terminal of the amplifier.

5. The bandgap reference circuit of claim 1, further comprising:
a fourth current source configured to generate a fourth current through the first node for a predetermined period when the bandgap reference circuit is enabled; and
a fifth current source configured to generate a fifth current through the second node for the predetermined period when the bandgap reference circuit is enabled.

6. The bandgap reference circuit of claim 5, further comprising a bias circuit, comprising:
a fourth PMOS transistor having a first terminal configured to receive a power voltage, a second terminal, and a control terminal configured to provide a bias voltage; and
a fifth PMOS transistor having a first terminal configured to receive the power voltage, a second terminal, and a control terminal coupled to the control terminal of the fourth PMOS transistor;
a first N-channel MOS (NMOS) transistor having a first terminal coupled to the second terminal of the fourth PMOS transistor, a second terminal configured to receive a system voltage, and a control terminal; and
a second NMOS transistor having a first terminal coupled to the second terminal of the fifth PMOS transistor, a second terminal configured to receive the system voltage, and the control terminal coupled to the first terminal of the second NMOS transistor;
wherein the fourth current source is configured to generate the fourth current according to the bias voltage, and the fifth current source is configured to generate the fifth current according to the bias voltage.

7. The bandgap reference circuit of claim 6, wherein:
the fourth current source comprises:
a sixth PMOS transistor having a first terminal configured to receive the power voltage, a second terminal, and a control terminal configured to receive the bias voltage; and
a first switch having a first terminal coupled to the second terminal of the sixth PMOS transistor, a second terminal coupled to the first node, and a control terminal configured to receive a start signal.

8. The bandgap reference circuit of claim 7, further comprising a pulse generator configured to generate the start signal with a pulse width equal to the predetermined period according to an enable signal of the bandgap reference circuit.

9. The bandgap reference circuit of claim 5, wherein a voltage calculated by dividing a product of the fourth current and a length of the predetermined period by a capacitance of the first capacitor is within an operating voltage range of the amplifier.

10. The bandgap reference circuit of claim 1, further comprising:
a second resistor having a first terminal coupled to the second node, and a second terminal;
wherein the first resistor has a first terminal coupled to the first node, and a second terminal
the first BJT has a first terminal coupled to the second terminal of the first resistor, a second terminal configured to receive the system voltage, and a control terminal coupled to the second terminal of the first BJT; and
wherein the second BJT has a first terminal coupled to the second terminal of the second resistor, a second terminal configured to receive the system voltage, and a control terminal coupled to the second terminal of the second BJT.

11. The bandgap reference circuit of claim 10, wherein a resistance of the first resistor is greater than a resistance of the second resistor.

12. The bandgap reference circuit of claim 10, wherein a resistance of the first resistor and a resistance of the second resistor are both greater than an on-resistance of the first BJT and an on-resistance of the second BJT.

13. The bandgap reference circuit of claim 1, wherein an impedance caused by the first capacitor at the first node for a ripple of the system voltage is lower than an impedance caused by the first BJT and an impedance caused by the second BJT for the ripple of the system voltage.

14. The bandgap reference circuit of claim 1, wherein:
the first resistor has a first terminal coupled to the first node, and a second terminal;
the first BJT has a first terminal coupled to the second terminal of the first resistor, a second terminal configured to receive the system voltage, and a control terminal coupled to the second terminal of the first BJT; and
the second BJT has a first terminal coupled to the second node, a second terminal configured to receive the system voltage, and a control terminal coupled to the second terminal of the second BJT.

15. The bandgap reference circuit of claim 1, further comprising a third BJT having a first terminal coupled to a second terminal of the load element, a second terminal configured to receive the system voltage, and a control terminal coupled to the second terminal of the third BJT;
wherein a first terminal of the load element is coupled to the output node.

16. A bandgap reference circuit, configured to generate and output a reference voltage and comprising:
an amplifier having a first input terminal coupled to a first node and a second input terminal coupled to a second node;
a first transistor path coupled to the first node and a second transistor path coupled to the second node, wherein the first and second transistor paths are configured to respectively generate a first current and a second current for generating the reference voltage;
a balancing circuit coupled to the first node and the second node, wherein the balancing circuit is configured to equalize a first impedance at the first node and a second impedance at the second node so as to reduce a voltage difference between the first node and the second node when a ripple appears in a system voltage; and
a charging circuit coupled to the first node and the second node, wherein the charging circuit is configured to, for a predetermined period upon enablement of the bandgap reference circuit, generate a first charging current through the first node and a second charging current through the second node to accelerate raising a voltage at the first node and a voltage at the second node into an operating voltage range of the amplifier.

17. The bandgap reference circuit of claim 16, wherein the balancing circuit comprises:
a first capacitor having a first terminal coupled to the first node, and a second terminal configured to receive a system voltage; and
a second capacitor having a first terminal coupled to the second node, and a second terminal configured to receive the system voltage;
wherein the charging circuit generates the first charging current and the second charging current for the predetermined period to charge the first capacitor and the second capacitor.

18. The bandgap reference circuit of claim 17, further comprising a pulse generator configured to generate, in the predetermined period, a start signal for activating the charging circuit to generate the first charging current and the second charging current according to an enable signal of the bandgap reference circuit.

19. The bandgap reference circuit of claim 17, wherein the voltage at the first node calculated by dividing a product of the first charging current and a length of the predetermined period by a capacitance of the first capacitor is within an operating voltage range of the amplifier.

20. The bandgap reference circuit of claim 16, wherein:
the first transistor path comprises:
a first current source configured to generate the first current through the first node;
a first bipolar junction transistor (BJT) configured to receive the first current; and
a first resistor coupled between the first node and the first BJT;
the second transistor path comprises:
a second current source configured to generate the second current through the second node; and
a second BJT configured to receive the second current.
